(19) United States
(12) Patent Application Publication
(10) Pub. No.: US 2011/0220909 A1
(43) Pub. Date: Sep. 15, 2011

(54) BACKPLANE STRUCTURES FOR SOLUTION PROCESSED ELECTRONIC DEVICES

(75) Inventors: Matthew Stainer, Goleta, CA (US); Yaw-Ming A. Tsai, Taichung (TW)

(73) Assignee: E.I. DU PONT DE NEMOURS AND COMPANY, Wilmington, DE (US)

(21) Appl. No.: 13/129,842

(22) PCT Filed: Dec. 4, 2009
(86) PCT No.: PCT/US09/66721

§ 371 Date: May 18, 2011

Related U.S. Application Data
(60) Provisional application No. 61/120,149, filed on Dec. 5, 2008.

(51) Int. Cl. H01L 29/786; H01L 21/44; H01L 21/445

(52) U.S. Cl. 257/72; 257/66; 438/669; 438/674; 257/E29.292; 257/E21.476; 257/E21.479

(57) ABSTRACT

There is provided a backplane for an organic electronic device. The backplane has a TFT substrate having a multiplicity of electrode structures thereon. There are spaces around the electrode structures and a layer of inorganic filler in the spaces. The thickness of the layer of inorganic filler is the same as the thickness of the electrode structures.

### RELATED APPLICATION

This application claims priority under 35 U.S.C. §119(e) from Provisional Application No. 61/120,149 filed on Dec. 5, 2008 and which is incorporated by reference in its entirety.

### BACKGROUND INFORMATION

1. Field of the Disclosure

This disclosure relates in general to electronic devices and processes for forming the same. More specifically, it relates to backplane structures and devices formed by solution processing using the backplane structures.

2. Description of the Related Art

Electronic devices, including organic electronic devices, continue to be more extensively used in everyday life. Examples of organic electronic devices include organic light-emitting diodes (“OLEDs”). A variety of deposition techniques can be used in forming layers used in OLEDs. Liquid deposition techniques include printing techniques such as ink-jet printing and continuous nozzle printing.

As the devices become more complex and achieve greater resolution, the use of active matrix circuitry with thin film transistors (“TFTs”) becomes more necessary. However, surfaces of most TFT substrates are not planar. Liquid deposition onto these non-planar surfaces can result in non-uniform films. The non-uniformity may be mitigated by the choice of solvent for the coating formulation and/or by controlling the drying conditions. However, there still exists a need for a TFT substrate design that will result in improved film uniformity.

### SUMMARY

There is provided a backplane for an organic electronic device comprising:

a TFT substrate;

a multiplicity of first electrode structures having a first thickness, wherein there are spaces around each of the electrode structures; and

a layer of inorganic filler in the spaces around each of the electrode structures, the inorganic filler having the same thickness as the electrode structures.

There is also provided a process for forming an organic electronic device, said process comprising:

forming a backplane comprising:
a TFT substrate;
a multiplicity of first electrode structures having a first thickness, wherein there are spaces around each of the electrode structures; and
a layer of inorganic filler in the spaces around each of the electrode structures, the inorganic filler having the same thickness as the electrode structures;

depositing onto at least a portion of the first electrode structures a first liquid composition comprising a first active material in a liquid medium; and

forming a second electrode.
There is also provided an organic electronic device comprising:

(i) a backplane comprising:
a TFT substrate;
a multiplicity of first electrode structures having a first thickness, wherein there are spaces around each of the electrode structures; and
a layer of inorganic filler in the spaces around each of the electrode structures, the inorganic filler having the same thickness as the electrode structures;

(ii) a hole transport layer in at least the pixel openings;

(iii) a photoactive layer in at least the pixel openings;

(iv) an electron transport layer in at least the pixel openings; and

(v) a cathode.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes as illustration, a schematic diagram of a tapered electrode.

FIG. 2 includes as illustration, a schematic diagram of a cross-sectional view of one embodiment of a new backplane as described herein.

FIG. 3 includes as illustration, a schematic diagram of a cross-sectional view of another backplane as described herein.

FIG. 4A includes as illustration, another schematic diagram of a backplane, as described herein.

FIG. 4B includes as illustration, the backplane of FIG. 4A having active organic layers thereon.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments are described in this specification and are merely exemplary and not limiting. After reading this specification, skilled artisans will appreciate that other aspects and embodiments are possible without departing from the scope of the invention.

Other features and benefits of any one or more of the embodiments will be apparent from the following detailed description, and from the claims. The detailed description first addresses Definitions and

Clarification of Terms followed by the Backplane, and the Process for Forming an Electronic Device.
1. Definitions and Clarification of Terms

Before addressing details of embodiments described below, some terms are defined or clarified. The defined terms are intended to include their variant forms.

As used herein, the term “active” when referring to a layer or material refers to a layer or material that electronically facilitates the operation of the device. Examples of active materials include, but are not limited to, materials that conduct, inject, transport, or block a charge, where the charge can be either an electron or a hole. Examples also include a layer or material that has electronic or electro-radiative properties. An active layer material may emit radiation or exhibit a change in concentration of electron-hole pairs when receiving radiation.

The term “active matrix” is intended to mean an array of electronic components and corresponding driver circuits within the array.

The term “backplane” is intended to mean a workpiece on which organic layers can be deposited to form an electronic device. The term “driver circuit” is intended to mean a circuit configured to control the activation of an electronic component, such as an organic electronic component.

The term “electronic device” is intended to mean a collection of circuits, electronic components, or combinations thereof that collectively, when properly connected and supplied with the proper potential(s), performs a function. An electronic device may include, or be part of, a system. Examples of electronic devices include displays, sensor arrays, computer systems, avionics, automobiles, cellular phones, and many other consumer and industrial electronic products. The term “insulative” is used interchangeably with “electrically insulating”. These terms and their variants are intended to refer to a material, layer, member, or structure having an electrical property such that it substantially prevents any significant current from flowing through such material, layer, member or structure.

The term “layer” is used interchangeably with the term “film” and refers to a coating covering a desired area. The area can be as large as an entire device or as small as a specific functional area such as the actual visual display, or as small as a single sub-pixel. Films can be formed by any conventional deposition technique, including vapor deposition, liquid deposition and thermal transfer. Typical liquid deposition techniques include, but are not limited to, continuous deposition techniques such as spin coating, gravure coating, curtain coating, dip coating, slot-die coating, spray coating, and continuous nozzle coating; and discontinuous deposition techniques such as ink jet printing, gravure printing, and screen printing.

The term “liquid composition” is intended to mean an organic active material that is dissolved in a liquid medium or media to form a solution, dispersed in a liquid medium or media to form a dispersion, or suspended in a liquid medium or media to form a suspension or an emulsion.

The term “organic electronic device” is intended to mean a device including one or more semiconductor layers or materials. Organic electronic devices include: (1) devices that convert electrical energy into radiation (e.g., an light-emitting diode, light emitting diode display, or diode laser), (2) devices that detect signals through electronics processes (e.g., photodetectors (e.g., photoconductive cells, photoresistors, photoswitches, phototransistors, or phototubes), IR detectors, or biosensors), (3) devices that convert radiation into electrical energy (e.g., a photovoltaic device or solar cell), and (4) devices that include one or more electronic components that include one or more organic semiconductor layers (e.g., a transistor or diode).

The term “overlying,” when used to refer to layers, members or structures within a device, does not necessarily mean that one layer, member or structure is immediately next to or in contact with another layer, member, or structure.

The term “structure” is intended to mean one or more patterned layers or members, which by itself or in combination with other patterned layer(s) or member(s), forms a unit that serves an intended purpose. Examples of structures include electrodes, well structures, cathode separators, and the like.

The term “TFT substrate” is intended to mean an array of TFTs and/or driving circuitry to make panel function on a base support. The term “support” or “base support” is intended to mean a base material that can be either rigid or flexible and may be include one or more layers of one or more materials, which can include, but are not limited to, glass, polymer, metal or ceramic materials or combinations thereof.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present). Also, use of “a” or “an” are employed to describe elements and components described herein. This is done merely for convenience and to give a general sense of the scope of the invention. This description should be read to include one or at least one and the singular also includes the plural unless it is obvious that it is meant otherwise. Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.
2. The Backplane

There is provided herein a new backplane for an electronic device. The backplane comprises:

a TFT substrate;

a multiplicity of first electrode structures having a first thickness, wherein there are spaces around each of the electrode structures; and

a layer of inorganic filler in the spaces around each of the electrode structures, the inorganic filler having the same thickness as the electrode structures.

TFT substrates are well known in the electronic arts. The base support may be a conventional support as used in organic electronic device arts. The base support can be flexible or rigid, organic or inorganic. In some embodiments, the base support is transparent. In some embodiments, the base support is glass or a flexible organic film. The TFT array may be located over or within the support, as is known.

The support can have a thickness in the range of about 12 to 2500 microns.

The term “thin-film transistor” or “TFT” is intended to mean a field-effect transistor in which at least a channel region of the field-effect transistor is not principally a portion of a base material of a substrate. In one embodiment, the channel region of a TFT includes a-Si, polycrystalline silicon, or a combination thereof. The term “field-effect transistor” is intended to mean a transistor, whose current carrying characteristics are affected by a voltage on a gate electrode. A field-effect transistor includes a junction field-effect transistor (JFET) or a metal-insulator-semiconductor field-effect transistor (MISFET), including a metal-oxide-semiconductor field-effect transistor (MOSFETs), a metal-nitride-oxide-semiconductor (MNOS) field-effect transistor, or the like. A field-effect transistor can be n-channel (n-type carriers flowing within the channel region) or p-channel (p-type carriers flowing within the channel region). A field-effect transistor may be an enhancement-mode transistor (channel region having a different conductivity type compared to the transistor's S/D regions) or depletion-mode transistor (the transistor's channel and S/D regions have the same conductivity type).

TFT structures and designs are well known. The TFT structure usually includes gate, source, and drain electrodes, and a sequence of inorganic insulating layers, usually referred to as a buffer layer, gate insulator, and interlayer.

A planarization layer is generally present over the TFT and driver structures in the TFT substrate. The planarization layer smoothes over the rough features and any particulate material of the TFT substrate, and minimizes parasitic capacitance. In some embodiments, the planarization layer is an organic layer. Any organic dielectric material can be used for the planarization layer. In some embodiments, the organic material is selected from the group consisting of epoxy resins, acrylic resins, and polyimide resins. Such resins are well known, and many are commercially available. The planarization layer can be formed and patterned as is well known in the art.

A multiplicity of first electrode structures are present on the planarization layer. The electrodes may be anodes or cathodes. In some embodiments, the electrodes are formed as parallel stripes. In some embodiments, the electrodes are pixellated. They may be formed in a patterned array of structures having plan view shapes, such as squares, rectangles, circles, triangles, ovals, and the like. Generally, the electrodes may be formed using conventional processes (e.g. deposition, patterning, or a combination thereof). The first electrode structures are spaced apart so that there are spaces around each of the electrode structures. By “around” it is meant that there are spaces on at least two sides of the electrode structures. In some embodiments, the spaces surround each electrode structure.

In some embodiments, the electrodes have a tapered edge with a taper angle of no greater than 75°. As used herein, the term “taper angle” as it refers to the electrode structure, is intended to mean the internal angle formed by the electrode edge and the underlying planarization layer. This is shown schematically in FIG. 1. Planarization layer 10 has an upper surface 11. Electrode structure 20, on the planarization layer, has a tapered edge 21. Tapered edge 21 forms an internal angle Θ with the planarization layer surface. Angle Θ is the taper angle. For a conventional, non-tapered electrode, the internal angle Θ will be 90°. In some embodiments, the electrodes have a taper angle of no greater than 75°; in some embodiments, no greater than 40°.

In some embodiments, the first electrode structures are tapered on at least the sides of the electrode that are parallel to the printing direction for the deposition of the organic active materials. In some embodiments, the first electrode structures are tapered on all sides.

In some embodiments, the electrodes are transparent. In some embodiments, the electrodes comprise a transparent conductive material such as indium-tin-oxide (ITO). Other transparent conductive materials include, for example, indium-zinc-oxide (IZO), zinc oxide, tin oxide, zinc-tin-oxide (ZTO), elemental metals, metal alloys, and combinations thereof. In some embodiments, the electrodes are anodes for the electronic device. The electrodes can be formed using conventional techniques, such as selective deposition using a stencil mask, or blanket deposition and a conventional lithographic technique to remove portions to form the pattern. The thickness of the first electrode structures is generally in the range of approximately 50 to 150 nm.

In the spaces around each of the first electrode structures there is a layer of inorganic filler material. The inorganic filler layer has the same thickness as the electrode structures. By “same thickness” it is meant that the thickness of the filler layer is within ±5% of the thickness of the first electrode structures. In some embodiments, the thickness is within ±1%.

Any inorganic dielectric material can be used as the filler material. In general, the inorganic material should have a dielectric constant of at least 2.5. In some embodiments, the inorganic material is selected from the group consisting of a metal oxide, a metal nitride, a metal oxynitride, and combinations thereof. In some embodiments, the inorganic material is selected from the group consisting of silicon oxides, silicon nitrides, and combinations thereof. In some embodiments the inorganic material may be selected from silica and silicon nitride.

The filler layer can be formed by any conventional process, such as deposition through a stencil mask. In some embodiments, the layer is formed by vapor deposition of a thin layer overall having about the same thickness as the first electrode structures. The inorganic layer on top of the electrode structures can then be removed. Any conventional technique can be used, such as lithographic techniques or chemical or plasma etching.

In some embodiments, the backplane is made by a process comprising:

providing a TFT substrate;

forming on the TFT substrate a multiplicity of first electrode structures having a first thickness, wherein there are spaces around each of the electrode structures;

depositing a layer of an inorganic filler material overall to a thickness greater than the first thickness; and

removing the inorganic filler material uniformly to a thickness the same as the first thickness, wherein the surface of the first electrode structures is uncovered, to form an essentially planar backplane.

In one embodiment of the process, the inorganic filler material is removed by chemical-mechanical polishing.

In the above process, the inorganic filler material is deposited overall in a thick layer. In some embodiments, the thickness is at least 5% greater than the thickness of the electrode structures; in some embodiments at least 10% greater. The filler material is then removed uniformly across the layer to make it the same thickness as the first electrode structures. At the same time, the filler material directly over the electrode structures is also removed. Any conventional technique can be used, as discussed above.

In some embodiments, chemical-mechanical polishing (“CMP”) is used to remove the filler material. CMP is a well-known technique that is used in the semiconductor industry to planarize a semiconductor wafer or other substrate. The process involves the combination of chemical and mechanical forces, and can be considered a hybrid of chemical etching and free abrasive polishing. Using CMP has the added advantage of smoothing out the surface of the electrode structures, and thus reduces the incidence of shorting defects.

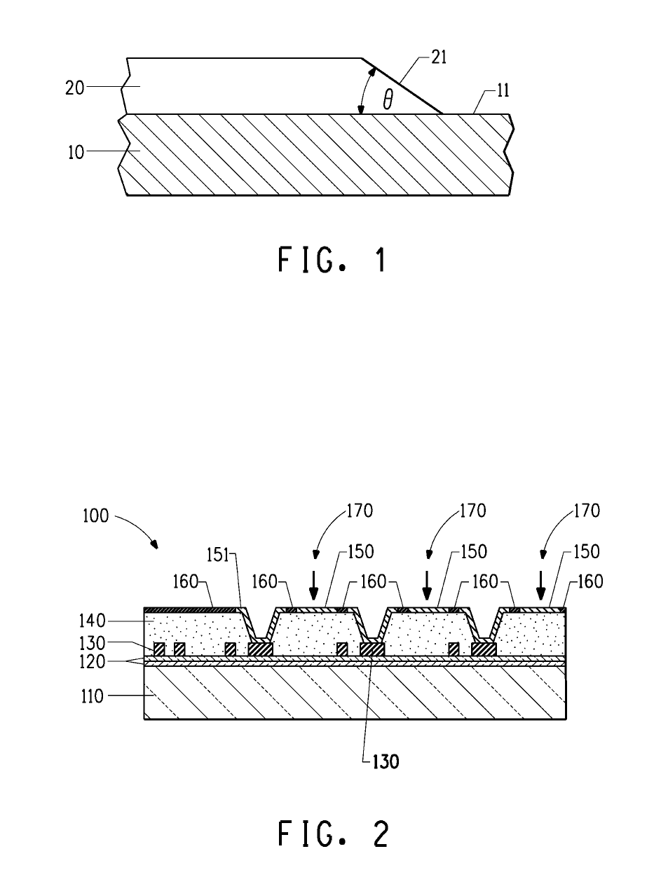

One exemplary backplane 100, with polycrystalline TFTs, is shown schematically in FIG. 2. The TFT substrate includes: glass substrate 110, inorganic insulative layers 120, and various conductive lines 130 for gate electrodes or gate lines and source/drain electrodes or data lines. There is an organic planarization layer 140. A pixellated electrode is shown as 150. There is metallization 151 for a via. The inorganic filler 160 is present in the spaces on either side of the electrode structures. The pixel areas 170, are over the electrodes. The pixel areas are where active organic materials will be deposited to form the device.

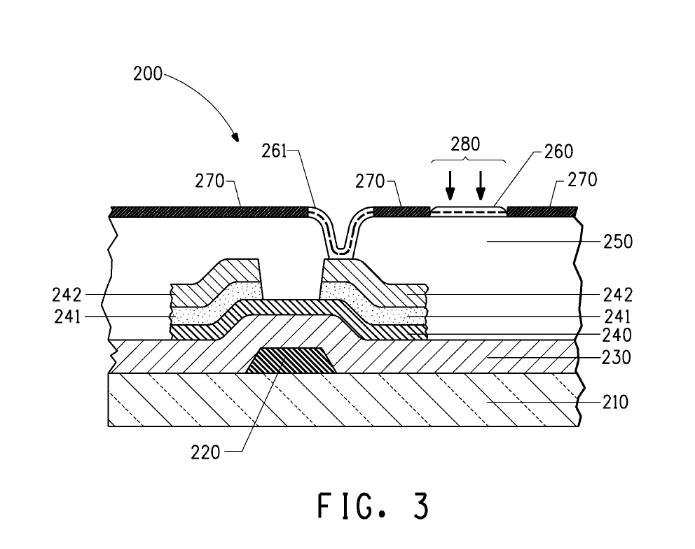

Another exemplary backplane with a-Si TFTs is shown schematically in FIG. 3 as 200. The TFT substrate includes: glass substrate 210, gate electrode or gate lines 220, gate insulator layer 230, a-Si channel 140, n⁺ a-Si contacts 241, and source/drain metals 242. The insulative layer 230 can be made of any inorganic insulative material, as is known in the art. The conductive layers 220 and 242 can be made of any inorganic conductive materials, as is known in the art. The a-Si channel and doped n⁺ a-Si layers are also well known in the art. Over the TFT substrate is organic planarization layer 250. The materials for the planarization layer have been discussed above. A patterned electrode 260 is formed over the planarization layer 250. There is metallization 261 for a via. The materials for the electrode have been discussed above. An inorganic filler material 270 is present around the electrode layer. The active organic materials will be deposited over the electrode in the pixel area 280 to form the device.

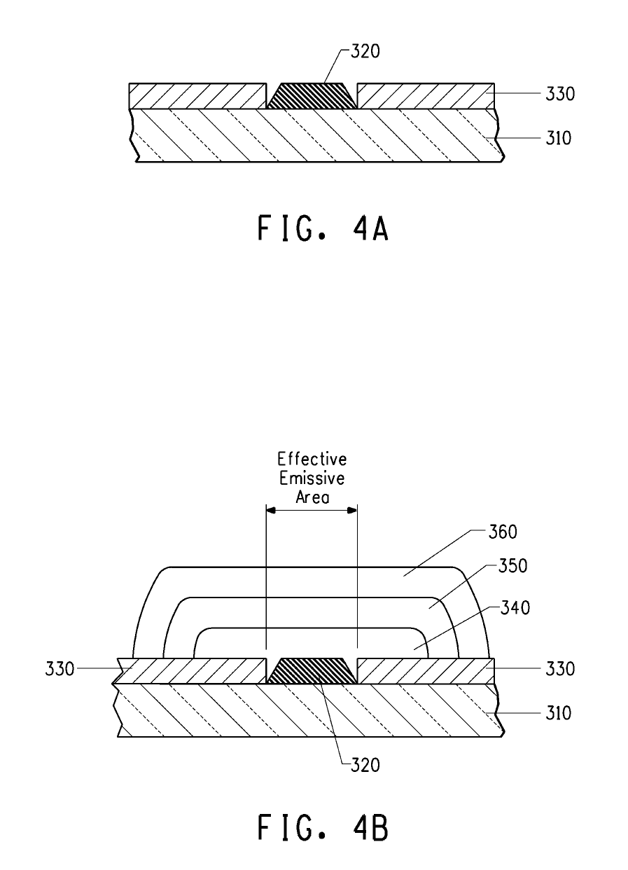

The backplanes described herein provide an essentially planar surface for the liquid deposition of active materials. This is shown schematically in FIGS. 4A and 4B. Backplane 300 is shown in FIG. 4A. On TFT substrate 310 there is electrode structure 320. Around the electrode structure are inorganic filler layers 330. The inorganic filler layers have the same thickness as the electrode structure. Thus backplane 300 has an essentially planar surface. In FIG. 4B the backplane is shown after the deposition of active layers: buffer layer 340, hole transport layer 350, and photoactive layer 360. The active layers have an essentially planar profile in the effective emissive area over the electrode structure.

The backplanes are particularly suited for liquid deposition by printing. Examples of printing techniques include ink-jet printing and continuous nozzle printing.
3. Process for Forming an Electronic Device

The backplane described herein is particularly suited to liquid deposition techniques for the organic active materials. A process for forming an organic electronic device comprises:

forming a backplane comprising:
a TFT substrate;
a multiplicity of first electrode structures having a first thickness, wherein there are spaces around each of the electrode structures; and
a layer of inorganic filler in the spaces around each of the electrode structures, the inorganic filler having the same thickness as the electrode structures;

depositing onto at least a portion of the first electrode structures a first liquid composition comprising a first active material in a first liquid medium to form a first active film; and

forming a second electrode.

As used herein, the term “depositing onto” does not necessarily mean that the deposition is directly on and in contact with the first electrode structures. In some embodiments, the first liquid composition comprises a buffer composition. In some embodiments, the first liquid composition comprises a hole transport material. In some embodiments, the first liquid composition comprises a photoactive material. In some embodiments, the first liquid composition is deposited directly onto and in contact with the first electrode structure.

In some embodiments, the process further comprises depositing onto at least a portion of the first active film a second liquid composition comprising a second active material in a second liquid medium, to form a second active film.

In some embodiments, the process further comprises depositing onto at least a portion of the second active film a third liquid composition comprising a third active material in a third liquid medium, to form a third active film.

An exemplary process for forming an electronic device includes forming one or more organic active layers on the electrode structures of the backplane described herein using liquid deposition techniques. In some embodiments, there are one or more photoactive layers and one or more charge transport layers. A second electrode is then formed over the organic layers, usually by a vapor deposition technique. Each of the charge transport layer(s) and the photoactive layer may include one or more layers. In another embodiment, a single layer having a graded or continuously changing composition may be used instead of separate charge transport and photoactive layers.

In some embodiments, there is provided an electronic device comprising:

(i) a backplane comprising:
a TFT substrate;
a multiplicity of first electrode structures having a first thickness, wherein there are spaces around each of the electrode structures; and
a layer of inorganic filler in the spaces around each of the electrode structures, the inorganic filler having the same thickness as the electrode structures;

(ii) a hole transport layer in at least the pixel openings;

(iii) a photoactive layer in at least the pixel openings;

(iv) an electron transport layer in at least the pixel openings; and

(v) a cathode.

In some embodiments, the device further comprises an organic buffer layer between the anode and the hole transport layer. In some embodiments, the device further comprises an electron injection layer between the electron transport layer and the cathode. In some embodiments, one or more of the buffer layer, the hole transport layer, the electron transport layer and the electron injection layer are formed overall.

In an exemplary embodiment, the electrode in the backplane is an anode. In some embodiments, a first organic layer comprising organic buffer material is applied by liquid deposition. In some embodiments, a first organic layer comprising hole transport material is applied by liquid deposition. In some embodiments, first layer comprising organic buffer material and a second layer comprising hole transport material are formed sequentially. After the organic buffer layer and/or hole transport layer are formed, a photoactive layer is formed by liquid deposition. Different photoactive compositions comprising red, green, or blue emitting-materials may be applied to different pixel areas to form a full color display. After the formation of the photoactive layer, an electron transport layer is formed by vapor deposition. After formation of the electron transport layer, an optional electron injection layer and then the cathode are formed by vapor deposition.

The term “organic buffer layer” or “organic buffer material” is intended to mean electrically conductive or semiconductive organic materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Organic buffer materials may be polymers, oligomers, or small molecules, and may be in the form of solutions, dispersions, suspensions, emulsions, colloidal mixtures, or other compositions.

The organic buffer layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The organic buffer layer can comprise charge transfer compounds, and the like, such as copper phthalocyanine and the tetrathiafulvalene-tetracyanoquinodimethane system (TTF-TCNQ). In one embodiment, the organic buffer layer is made from a dispersion of a conducting polymer and a colloid-forming polymeric acid. Such materials have been described in, for example, published U.S. patent applications 2004/0102577, 2004/0127637, and 2005/205860. The organic buffer layer typically has a thickness in a range of approximately 20-200 nm.

The term “hole transport,” when referring to a layer, material, member, or structure is intended to mean such layer, material, member, or structure facilitates migration of positive charge through the thickness of such layer, material, member, or structure with relative efficiency and small loss of charge. Although light-emitting materials may also have some charge transport properties, the term “charge transport layer, material, member, or structure” is not intended to include a layer, material, member, or structure whose primary function is light emission.

Examples of hole transport materials for layer 120 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl] pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate. The hole transport layer may also be doped with a p-dopant, such as tetrafluorotetracyanoquinodimethane and perylene-3,4,9,10-tetracarboxylic-3,4,9,10-dianhydride. The hole transport layer typically has a thickness in a range of approximately 40-100 nm.

The term “photoactive” refers to a material that emits light when activated by an applied voltage (such as in a light emitting diode or chemical cell) or responds to radiant energy and generates a signal with or without an applied bias voltage (such as in a photodetector). Any organic electroluminescent (“EL”) material can be used in the photoactive layer, and such materials are well known in the art. The materials include, but are not limited to, small molecule organic fluorescent compounds, fluorescent and phosphorescent metal complexes, conjugated polymers, and mixtures thereof. The photoactive material can be present alone, or in admixture with one or more host materials. Examples of fluorescent compounds include, but are not limited to, naphthalene, anthracene, chrysene, pyrene, tetracene, xanthene, perylene, coumarin, rhodamine, quinacridone, rubrene, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Examples of conjugated polymers include, but are not limited to poly(phenylenevinylenes), polyfluorenes, poly(spirobifluorenes), polythiophenes, poly(p-phenylenes), copolymers thereof, and mixtures thereof. The photoactive layer 1912 typically has a thickness in a range of approximately 50-500 nm.

“Electron Transport” means when referring to a layer, material, member or structure, such a layer, material, member or structure that promotes or facilitates migration of negative charges through such a layer, material, member or structure into another layer, material, member or structure. Examples of electron transport materials which can be used in the optional electron transport layer 140, include metal chelated oxinoid compounds, such as tris(8-hydroxyquinolato)aluminum (AIQ), bis(2-methyl-8-quinolinolato)(p-phenylphenolato) aluminum (BAIq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. The electron-transport layer may also be doped with n-dopants, such as Cs or other alkali metals. The electron-transport layer typically has a thickness in a range of approximately 30-500 nm.

As used herein, the term “electron injection” when referring to a layer, material, member, or structure, is intended to mean such layer, material, member, or structure facilitates injection and migration of negative charges through the thickness of such layer, material, member, or structure with relative efficiency and small loss of charge. The optional electron-transport layer may be inorganic and comprise BaO, LiF, or Li₂O.

The electron injection layer typically has a thickness in a range of approximately 20-100 Å.

The cathode can be selected from Group 1 metals (e.g., Li, Cs), the Group 2 (alkaline earth) metals, the rare earth metals including the lanthanides and the actinides. The cathode a thickness in a range of approximately 300-1000 nm.

An encapsulating layer can be formed over the array and the peripheral and remote circuitry to form a substantially complete electrical device.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes slight variations above and below such values, and the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

What is claimed is:

1. A backplane for an organic electronic device comprising:
a TFT substrate;
a multiplicity of first electrode structures having a first thickness, wherein there are spaces around each of the electrode structures; and
a layer of inorganic filler in the spaces around each of the electrode structures, the inorganic filler having the same thickness as the electrode structures.

2. The backplane of claim 1, wherein the electrode structures have a tapered edge with a taper angle no greater than 75°.

3. The backplane of claim 1, wherein the inorganic filler material is selected from a metal oxide, metal nitride, and metal oxynitride.

4. The backplane of claim 1, wherein the inorganic filler material is selected from the group consisting of silicon oxides, silicon nitrides, and combinations thereof.

5. A process for forming a backplane for an electronic device, said process comprising:
providing a TFT substrate;
forming on the TFT substrate a multiplicity of first electrode structures having a first thickness, wherein there are spaces around each of the electrode structures;
depositing a layer of an inorganic filler material overall to a thickness greater than the first thickness; and
removing the inorganic filler material uniformly to a thickness the same as the first thickness, wherein the surface of the first electrode structures is uncovered, to form an essentially planar backplane.

6. The process of claim 5, wherein the inorganic filler material is removed by chemical-mechanical polishing.

7. A process for forming an organic electronic device, comprising:
forming a backplane comprising:
a TFT substrate;
a multiplicity of first electrode structures having a first thickness, wherein there are spaces around each of the electrode structures; and
a layer of inorganic filler in the spaces around each of the electrode structures, the inorganic filler having the same thickness as the electrode structures; and
depositing onto at least a portion of the first electrode structures a first liquid composition comprising a first active material in a liquid medium to form a first active film.

8. The process of claim 7, further comprising depositing onto at least a portion of the first active film a second liquid composition comprising a second active material in a second liquid medium, to form a second active film.

9. The process of claim 8, further comprising depositing onto at least a portion of the second active film a third liquid composition comprising a third active material in a third liquid medium, to form a third active film.

10. An electronic device comprising:
(i) a backplane comprising:
a TFT substrate;
a multiplicity of first electrode structures having a first thickness, wherein there are spaces around each of the electrode structures; and
a layer of inorganic filler in the spaces around each of the electrode structures, the inorganic filler having the same thickness as the electrode structures;
(ii) a hole transport layer in at least the pixel openings;
(iii) a photoactive layer in at least the pixel openings;
(iv) an electron transport layer in at least the pixel openings; and
(v) a cathode.

11. The device of claim 10, further comprising an organic buffer layer between the anode and the hole transport layer.

12. The device of claim 10, further comprising an electron injection layer between the electron transport layer and the cathode.
